(19) United States
(12) Patent Application Publication
(10) Pub. No.: US 2025/0309605 A1
(43) Pub. Date: Oct. 2, 2025

(54) CHAMBER DEVICE, GAS LASER DEVICE, AND ELECTRONIC DEVICE MANUFACTURING METHOD

(71) Applicant: Gigaphoton Inc., Tochigi (JP)

(72) Inventors: Takeshi UEYAMA, Oyama-shi (JP); Hiroshi UMEDA, Oyama-shi (JP)

(73) Assignee: Gigaphoton Inc., Tochigi (JP)

(21) Appl. No.: 19/047,910

(22) Filed: Feb. 7, 2025

(30) Foreign Application Priority Data
Mar. 26, 2024 (JP) 2024-050139

(51) Int. Cl. H01S 3/0975; G03F 7/00

(52) U.S. Cl. CPC H01S 3/0975; G03F 7/70025

(57) ABSTRACT

A chamber device includes a pair of discharge electrodes arranged with a longitudinal direction oriented along a predetermined direction as being apart from and facing each other; a chamber having an internal space where the pair of discharge electrodes are arranged; capacitors arranged in parallel along the predetermined direction; a power supply terminal electrically connecting one discharge electrode and one terminal of each capacitor to a high-voltage power source; and a connection member extending in the predetermined direction, electrically connected to the other terminal of each capacitor, and having a portion away from a side electrically connected to the other terminal in the direction perpendicular to the predetermined direction be connected to the ground. The connection member includes an inductance compensation structure that makes a distribution of inductance due to a distance between the power supply terminal and the one terminal of each of the capacitors close to be uniform.

### CROSS-REFERENCE TO RELATED APPLICATIONS

The present application claims the benefit of Japanese Patent Application No. 2024/050139, filed on Mar. 26, 2024, the entire contents of which are hereby incorporated by reference.

### BACKGROUND

### 1. Technical Field

The present disclosure relates to a chamber device, a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 μm to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. H11-163447
Patent Document 2: Japanese Patent Application Publication No. 2006-24600

### SUMMARY

A chamber device according to an aspect of the present disclosure includes a pair of discharge electrodes arranged with a longitudinal direction thereof oriented along a predetermined direction as being apart from and facing each other; a chamber having an internal space at which the pair of discharge electrodes are arranged and a laser gas is enclosed; a plurality of capacitors arranged in parallel along the predetermined direction; at least one power supply terminal electrically connecting one of the discharge electrodes and one terminal of each capacitor to a high-voltage power source; and a conductive plate-shaped connection member extending in the predetermined direction along the plurality of capacitors, electrically connected to the other terminal of each capacitor, and having a portion away from a side electrically connected to the other terminal in the direction perpendicular to the predetermined direction be connected to the ground. Here, the connection member includes an inductance compensation structure that makes a distribution of inductance due to a distance between the power supply terminal and the one terminal of each of the capacitors close to be uniform.

A gas laser device according to an aspect of the present disclosure is configured to amplify laser light by a chamber device and output the laser light. Here, the chamber device includes a pair of discharge electrodes arranged with a longitudinal direction thereof oriented along a predetermined direction as being apart from and facing each other; a chamber having an internal space at which the pair of discharge electrodes are arranged and a laser gas is enclosed; a plurality of capacitors arranged in parallel along the predetermined direction; at least one power supply terminal electrically connecting one of the discharge electrodes and one terminal of each capacitor to a high-voltage power source; and a conductive plate-shaped connection member extending in the predetermined direction along the plurality of capacitors, electrically connected to the other terminal of each capacitor, and having a portion away from a side connected to the other terminal in the direction perpendicular to the predetermined direction be electrically connected to the chamber. The connection member includes an inductance compensation structure that makes a distribution of inductance due to a distance between the power supply terminal and the one terminal of each of the capacitors close to be uniform.

An electronic device manufacturing method according to an aspect of the present disclosure includes generating laser light using a gas laser device configured to amplify laser light by a chamber device and output the laser light, outputting the laser light to an exposure apparatus, and exposing a photosensitive substrate to the laser light in the exposure apparatus to manufacture an electronic device.

Here, the chamber device includes a pair of discharge electrodes arranged with a longitudinal direction thereof oriented along a predetermined direction as being apart from and facing each other; a chamber having an internal space at which the pair of discharge electrodes are arranged and a laser gas is enclosed; a plurality of capacitors arranged in parallel along the predetermined direction; at least one power supply terminal electrically connecting one of the discharge electrodes and one terminal of each capacitor to a high-voltage power source; and a conductive plate-shaped connection member extending in the predetermined direction along the plurality of capacitors, electrically connected to the other terminal of each capacitor, and having a portion away from a side connected to the other terminal in the direction perpendicular to the predetermined direction be electrically connected to the chamber. The connection member includes an inductance compensation structure that makes a distribution of inductance due to a distance between the power supply terminal and the one terminal of each of the capacitors close to be uniform.

### BRIEF DESCRIPTION OF THE DRAWINGS

Embodiments of the present disclosure will be described below merely as examples with reference to the accompanying drawings.

FIG. 1 is a schematic diagram showing a schematic configuration example of an entire electronic device manufacturing apparatus.

FIG. 2 is a schematic diagram showing a schematic configuration example of an entire gas laser device of a comparative example.

FIG. 3 is a sectional view, perpendicular to a travel direction of the laser light, of the chamber device of the comparative example.

FIG. 4 is an electric circuit diagram of the gas laser device of the comparative example.

FIG. 5 is a view of a circuit of the comparative example connected to a pulse power module viewed from the above.

FIG. 6 is a graph showing the relationship between the distance from a power supply terminal to each capacitor, the capacitance of each capacitor, the cycle of charge of each capacitor, and the inductance of each circuit.

FIG. 7 is a view showing the circuit of a first embodiment connected to the pulse power module in the same manner as in FIG. 5.

FIG. 8 is a view showing the circuit of a first modification of the first embodiment connected to the pulse power module in the same manner as in FIG. 5.

FIG. 9 is a view showing the circuit of a second modification of the first embodiment connected to the pulse power module in the same manner as in FIG. 5.

FIG. 10 is a view showing the circuit of a third modification of the first embodiment connected to the pulse power module in the same manner as in FIG. 5.

FIG. 11 is a view showing the circuit of a fourth modification of the first embodiment connected to the pulse power module in the same manner as in FIG. 5.

FIG. 12 is a view showing the circuit of a fifth modification of the first embodiment connected to the pulse power module in the same manner as in FIG. 5.

FIG. 13 is a view showing the circuit of a sixth modification of the first embodiment connected to the pulse power module in the same manner as in FIG. 6.

FIG. 14 is a view showing the circuit of a second embodiment connected to the pulse power module in the same manner as in FIG. 5.

FIG. 15 is a view showing the circuit of a first modification of the second embodiment connected to the pulse power module in the same manner as in FIG. 5.

FIG. 16 is a view showing the circuit of a second modification of the second embodiment connected to the pulse power module in the same manner as in FIG. 5.

FIG. 17 is a view showing the circuit of a third modification of the second embodiment connected to the pulse power module in the same manner as in FIG. 5.

FIG. 18 is a view showing the circuit of a fourth modification of the second embodiment connected to the pulse power module in the same manner as in FIG. 5.

FIG. 19 is a view showing the circuit of a third embodiment connected to the pulse power module in the same manner as in FIG. 5.

FIG. 20 is a view showing the circuit of a fourth embodiment connected to the pulse power module in the same manner as in FIG. 5.

FIG. 21 is a view showing the circuit of a fifth embodiment connected to the pulse power module in the same manner as in FIG. 5.

### DESCRIPTION OF EMBODIMENTS

1. Description of electronic device manufacturing apparatus used in exposure process for electronic device
2. Description of gas laser device of comparative example
   2.1 Configuration
   2.2 Operation
   2.3 Problem
3. Description of gas laser device of first embodiment
   3.1 Configuration
   3.2 Effect
   3.3 First modification
   3.4 Second modification
   3.5 Third modification
   3.6 Fourth modification
   3.7 Fifth modification
   3.8 Sixth modification
4. Description of gas laser device of second embodiment
   4.1 Configuration
   4.2 Effect
   4.3 First modification
   4.4 Second modification
   4.5 Third modification
   4.6 Fourth modification
5. Description of gas laser device of third embodiment
   5.1 Configuration
   5.2 Effect
6. Description of gas laser device of fourth embodiment
   6.1 Configuration
   6.2 Effect
7. Description of gas laser device of fifth embodiment
   7.1 Configuration
   7.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted. 1. Description of electronic device manufacturing apparatus used in exposure process for electronic device

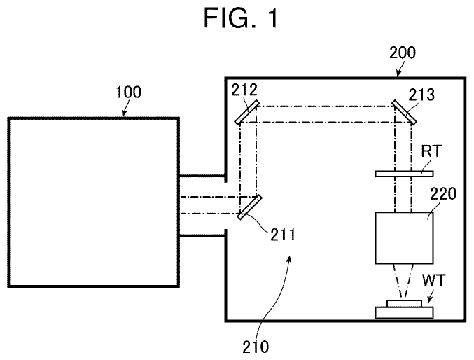

FIG. 1 is a schematic diagram showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is the electronic device, can be manufactured.

2. Description of gas laser device of comparative example

2.1 Configuration

The gas laser device of a comparative example will be described. The comparative example of the present disclosure is an example recognized by the applicant as known only by the applicant, and is not a publicly known example admitted by the applicant.

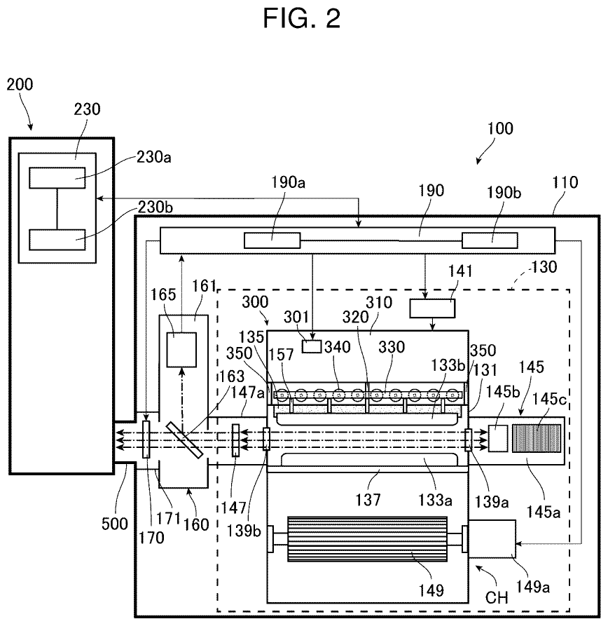

FIG. 2 is a schematic diagram showing a schematic configuration example of the entire gas laser device 100 of the comparative example. The gas laser device 100 is, for example, an ArF excimer laser device using a mixed gas including argon (Ar), fluorine (F₂), and neon (Ne). The gas laser device 100 outputs laser light having a center wavelength of about 193.4 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs laser light having a center wavelength of about 248 nm. The mixed gas containing Ar, F₂, and Ne which is a laser medium and the mixed gas containing Kr, F₂, and Ne which is a laser medium may be each referred to as a laser gas. In FIG. 2, the internal configuration of a chamber device CH is shown as a sectional view along a travel direction of the laser light. Along the travel direction of the laser light, the left side of the paper surface in FIG. 2 is referred to as a front side, the right side of the paper surface is referred to as a rear side, the upper side of the paper surface is referred to as above, and the lower side of the paper surface is referred to as below.

The gas laser device 100 includes a housing 110, and a laser oscillator 130, a monitor module 160, a shutter 170, and a laser device processor 190 arranged at the internal space of the housing 110 as a main configuration.

The laser oscillator 130 includes the chamber device CH, a charger 141, a line narrowing module 145, an output coupling mirror 147, and a pulse compression circuit 300.

The chamber device CH includes a chamber 131. An upper portion of the chamber 131 is open, and is blocked by an electrically insulating plate 135. The chamber 131 is made of a conductive material, and examples of the material include a metal such as nickel-plated aluminum and nickel-plated stainless steel. The chamber 131 is electrically connected to the ground. The chamber 131 includes an internal space in which light is generated by excitation of a laser medium in the laser gas. The laser gas is supplied from a laser gas supply source (not shown) to the internal space of the chamber 131 through a pipe (not shown). Further, the laser gas in the chamber 131 is subjected to a process of removing an Fe gas by a halogen filter or the like, and is exhausted to the housing 110 through a pipe (not shown) by an exhaust pump (not shown).

The electrically insulating plate 135 includes an insulator. Examples of the material of the electrically insulating plate 135 include alumina ceramics having low reactivity with an F: gas. The electrically insulating plate 135 may have electrical insulation, and examples of the material of the electrically insulating plate 135 include a resin such as a phenol resin and a fluoro-resin, quartz, and glass.

At the internal space of the chamber 131, an electrode 133a which is a first main electrode and an electrode 133b which is a second main electrode face each other with a space therebetween, and the longitudinal direction of each thereof is arranged along a predetermined direction which is the travel direction of the laser light. In the present example, the electrode 133b is located directly above the electrode 133a. The electrodes 133a, 133b are discharge electrodes for exciting the laser medium by glow discharge. In the present example, the electrode 133a is the anode and the electrode 133b is the cathode.

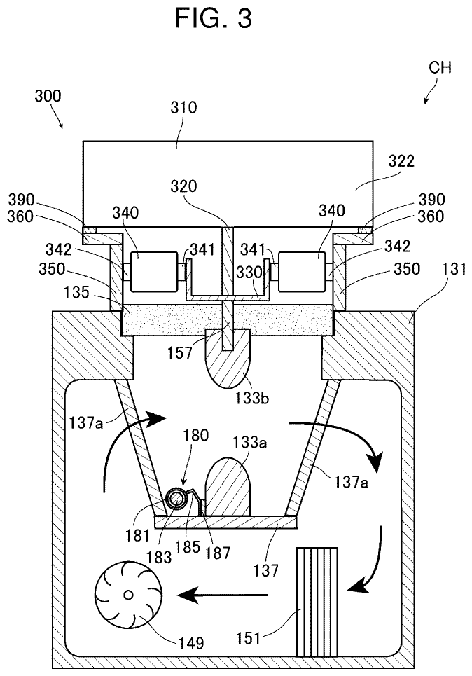

FIG. 3 is a sectional view, perpendicular to the travel direction of the laser light, of the chamber device CH of the comparative example. As shown in FIGS. 2 and 3, the electrode 133a is supported by an electrode holder portion 137 and is electrically connected to the electrode holder portion 137. The electrode holder portion 137 is electrically connected to the chamber 131 via wirings 137a. Therefore, the electrode 133a supported by the electrode holder portion 137 is electrically connected to the ground via the electrode holder portion 137, the wirings 137a, and the chamber 131. Further, the chamber 131 is electrically connected to a holder 350, and the holder 350 is electrically connected to the ground.

The electrode 133b is fixed to a surface of the electrically insulating plate 135 on a side facing the internal space of the chamber 131 by feedthroughs 157 which are current introduction terminals being, for example, bolts. The feedthroughs 157 are electrically connected to the pulse compression circuit 300 and other circuit components, and ensure conduction between the pulse compression circuit 300 and the electrode 133b.

The charger 141 is a DC high-voltage power source that supplies electric energy to the pulse compression circuit 300. The pulse compression circuit 300 is arranged on the holder 350 and generates a pulse high voltage from the electric energy held in the charger 141 to apply the high voltage between the electrode 133a and the electrode 133b.

When the high voltage is applied between the electrode 133a and the electrode 133b, glow discharge occurs between the electrode 133a and the electrode 133b. The laser medium in the chamber 131 is excited by the energy of the discharge, and the excited laser medium emits light when shifting to the ground state.

A preionization electrode 180 is provided on the electrode holder portion 137 beside the electrode 133a. The preionization electrode 180 includes a dielectric pipe 181, a preionization inner electrode 183, and a preionization outer electrode 185.

The dielectric pipe 181 is, for example, a cylindrical pipe arranged such that the longitudinal direction thereof is oriented along a predetermined direction. The dielectric pipe 181 is made of, for example, alumina ceramics or sapphire. The preionization inner electrode 183 has a rod shape, is arranged inside the dielectric pipe 181, and extends along the longitudinal direction of the dielectric pipe 181. The preionization inner electrode 183 is made of, for example, copper or brass. The preionization outer electrode 185 is arranged between the dielectric pipe 181 and the electrode 133a, and extends along the longitudinal direction of the dielectric pipe 181. An end portion of the preionization outer electrode 185 is in contact with the outer peripheral surface of the dielectric pipe 181. Here, at least a part of the end portion of the preionization outer electrode 185 may not be in contact with the outer peripheral surface of the dielectric pipe 181 as long as corona discharge described later occurs. The preionization outer electrode 185 is fixed to a spacer 187 fixed to the electrode 133a.

The preionization inner electrode 183 is electrically connected to the pulse compression circuit 300 via a preionization capacitor described later. The preionization outer electrode 185 is electrically connected to the electrode 133a via the electrode holder portion 137, and is electrically connected to the chamber 131 via the electrode holder portion 137 and the wirings 137a. Therefore, the preionization outer electrode 185 is electrically connected to the ground. When a high voltage is applied from the pulse compression circuit 300 to the preionization inner electrode 183 and the preionization outer electrode 185, corona discharge occurs in the vicinity of the end portion of the preionization outer electrode 185. The corona discharge assists stable generation of glow discharge which occurs between the electrodes 133a, 133b.

A pair of windows 139a, 139b are arranged on a wall surface of the chamber 131. The window 139a is located at one end side of the chamber 131 in the travel direction of the laser light, the window 139b is located at the other end side in the travel direction, and the windows 139a, 139b sandwich a space between the electrode 133a and the electrode 133b. The windows 139a, 139b may be inclined at the Brewster angle with respect to the travel direction of the laser light so that reflection of the laser light is suppressed. The laser light oscillated as described later is output to the outside of the chamber 131 through the windows 139a, 139b. Since a pulse high voltage is applied between the electrode 133a and the electrode 133b by the pulse compression circuit 300 as described above, the laser light is pulse laser light.

A cross flow fan 149 and a heat exchanger 151 are further arranged at the internal space of the chamber 131. The cross flow fan 149 and the heat exchanger 151 are arranged on a side opposite to the electrode 133a with respect to the electrode holder portion 137. In the chamber 131, the space at which the cross flow fan 149 and the heat exchanger 151 are arranged is in communication with the space between the electrode 133a and the electrode 133b. The heat exchanger 151 is a radiator arranged beside the cross flow fan 149 and connected to a pipe (not shown) through which a cooling medium flows. As shown in FIG. 2, the cross flow fan 149 is connected to a motor 149a arranged outside the chamber 131, and rotates with rotation of the motor 149a. As the cross flow fan 149 rotates, the laser gas enclosed at the internal space of the chamber 131 circulates as indicated by arrows in FIG. 3. At least a part of the circulating laser gas passes through the heat exchanger 151, so that the temperature of the laser gas is adjusted.

The line narrowing module 145 includes a housing 145a, and a prism 145b, a grating 145c, and a rotation stage (not shown) arranged at the internal space of the housing 145a. An opening is formed in the housing 145a, and the housing 145a is connected to the rear side of the chamber 131 through the opening.

The prism 145b expands the beam width of the light output from the window 139a and causes the light to be incident on the grating 145c. Further, the prism 145b also reduces the beam width of the reflection light from the grating 145c and returns the light to the internal space of the chamber 131 through the window 139a. The prism 145b is supported by the rotation stage and is rotated by the rotation stage. The incident angle of the light on the grating 145c is changed by the rotation of the prism 145b, so that the wavelength of the light returning from the grating 145c to the chamber 131 via the prism 145b can be selected. Although FIG. 2 shows an example in which one prism 145b is arranged, at least one prism may be arranged.

The surface of the grating 145c is configured of a material having a high reflectance, and a large number of grooves are formed on the surface at predetermined intervals. The sectional shape of each groove is, for example, a right-angled triangle. The light incident on the grating 145c from the prism 145b is diffracted in a direction corresponding to the wavelength of the light when reflected by the grooves. The grating 145c is arranged in the Littrow arrangement, which causes the incident angle of the light incident on the grating 145c from the prism 145b to coincide with the diffraction angle of the diffracted light having a desired wavelength. Thus, light having a wavelength close to the desired wavelength returns into the chamber 131 via the prism 145b.

The output coupling mirror 147 is arranged at the internal space of an optical path pipe 147a connected to the front side of the chamber 131, and faces the window 139b. The output coupling mirror 147 transmits a part of the laser light output from the window 139b toward the monitor module 160, and reflects another part of the laser light to return to the internal space of the chamber 131 through the window 139b. Thus, the grating 145c and the output coupling mirror 147 configure a Fabry-Perot laser resonator.

The monitor module 160 is arranged on the optical path of the laser light output from the output coupling mirror 147. The monitor module 160 includes a housing 161, and a beam splitter 163 and an optical sensor 165 arranged at the internal space of the housing 161. An opening is formed in the housing 161, and the internal space of the housing 161 communicates with the internal space of the optical path pipe 147a through the opening.

The beam splitter 163 transmits a part of the laser light output from the output coupling mirror 147 toward the shutter 170, and reflects another part of the laser light toward a light receiving surface of the optical sensor 165. The optical sensor 165 outputs a signal indicating an energy E of the laser light incident on the light receiving surface thereof to the laser device processor 190.

The laser device processor 190 of the present disclosure is a processing device including a storage device 190a in which a control program is stored and a central processing unit (CPU) 190b that executes the control program. The laser device processor 190 is specially configured or programmed to perform various processes included in the present disclosure. The laser device processor 190 controls the entire gas laser device 100.

The laser device processor 190 transmits and receives various signals to and from an exposure apparatus processor 230 of the exposure apparatus 200. For example, the laser device processor 190 receives signals indicating a later-described light emission trigger Tr and a later-described target energy Et from the exposure apparatus processor 230. The target energy Et is a target value of the energy of the laser light to be used in the exposure process. The laser device processor 190 controls the charge voltage of the charger 141 based on the energy E and the target energy Et received from the optical sensor 165 and the exposure apparatus processor 230, respectively. By controlling the charge voltage, the energy of the laser light is controlled. The laser device processor 190 is electrically connected to the shutter 170 and controls opening and closing of the shutter 170.

The laser device processor 190 closes the shutter 170 until a difference ΔE between the energy E received from the monitor module 160 and the target energy Et received from the exposure apparatus processor 230 falls within an allowable range. When the difference ΔE falls within the allowable range, the laser device processor 190 transmits, to the exposure apparatus processor 230, a reception preparation completion signal indicating that reception preparation of the light emission trigger Tr is completed. The exposure apparatus processor 230 transmits a signal indicating the light emission trigger Tr to the laser device processor 190 when receiving the reception preparation completion signal, and the laser device processor 190 opens the shutter 170 when receiving the signal indicating the light emission trigger Tr. The light emission trigger Tr is a timing signal for the exposure apparatus processor 230 to cause the laser oscillator 130 to perform laser oscillation, and is an external trigger. The light emission trigger Tr is defined by a predetermined repetition frequency f and a predetermined number of pulses P of the laser light. The repetition frequency f of the laser light is, for example, equal to or higher than 100 Hz and equal to or lower than 10 KHZ.

The shutter 170 is arranged on the optical path at the internal space of an optical path pipe 171 communicating with an opening formed at the housing 161 of the monitor module 160 on a side opposite to the side to which the optical path pipe 147a is connected. The internal spaces of the optical path pipes 171, 147a and the internal spaces of the housings 161, 145a are supplied and filled with a purge gas. The purge gas includes an inert gas such as nitrogen (N₂). The purge gas is supplied from a purge gas supply source (not shown) through a pipe (not shown). The optical path pipe 171 is in communication with the exposure apparatus 200 through the opening of the housing 110 and the optical path pipe 500 connecting the housing 110 and the exposure apparatus 200. The laser light having passed through the shutter 170 enters the exposure apparatus 200.

The exposure apparatus processor 230 of the present disclosure is a processing device including a storage device 230a in which a control program is stored and a CPU 230b that executes the control program. The exposure apparatus processor 230 is specifically configured or programmed to perform various processes included in the present disclosure. Further, the exposure apparatus processor 230 controls the entire exposure apparatus 200.

Next, the configuration of the pulse compression circuit 300 will be described.

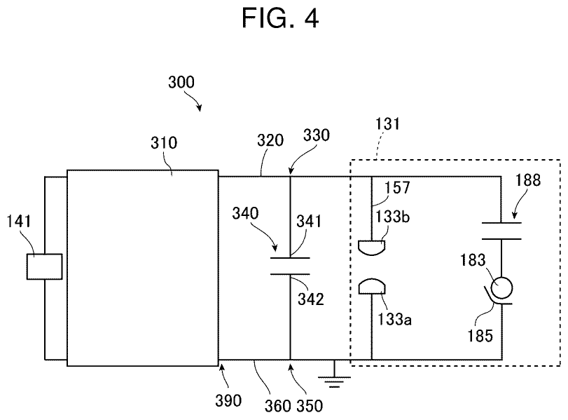

FIG. 4 is an electric circuit diagram of the gas laser device 100 of the present example. As shown in FIG. 4, the pulse compression circuit 300 of the gas laser device 100 includes a pulse power module 310 connected to the charger 141 and a plurality of capacitors 340 that store energy from the pulse power module 310. The capacitors 340 may be referred to as peaking capacitors. In FIG. 4, the plurality of capacitors 340 are collectively represented by one symbol.

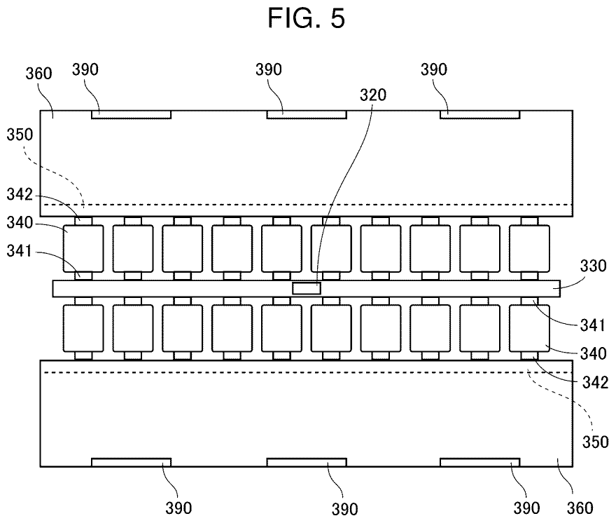

FIG. 5 is a view of a circuit connected to the pulse power module 310 viewed from the above. As shown in FIGS. 2 to 5, the circuit between the pulse power module 310 and the electrodes 133a, 133b includes a power supply terminal 320 derived from the inside of the pulse power module 310, a connection plate 330, the plurality of capacitors 340, the feedthroughs 157, the holder 350, and a connection member 360 as a main configuration.

The pulse power module 310 includes a switch 301. The switch 301 is electrically connected to the charger 141 and is controlled by the laser device processor 190. When the switch 301 is turned on, a current flows from the pulse power module 310 to the power supply terminal 320.

In the present example, there is only one power supply terminal 320. The connection plate 330 is connected to the power supply terminal 320, and the power supply terminal 320 and the connection plate 330 are electrically connected to each other. The connection plate 330 is a conductive plate whose longitudinal direction is arranged along the predetermined direction that is the longitudinal direction of the electrode 133b. In the present example, the power supply terminal 320 is connected to the connection plate 330 substantially at the center in the longitudinal direction of the connection plate 330. The shape of the cross section perpendicular to the longitudinal direction of the connection plate 330 is generally U-shaped as shown in FIG. 3. In the cross section, both ends of the connection plate 330 are bent toward the pulse power module 310.

The feedthroughs 157 are connected to the side of the connection plate 330 opposite to the side to which the power supply terminal 320 is connected, and the connection plate 330 and the feedthroughs 157 are electrically connected to each other. In the present example, one feedthrough 157 is provided directly below the power supply terminal 320, and pairs of two feedthroughs 157 are provided along the longitudinal direction of the connection plate 330 so as to sandwich the one feedthrough 157. Thus, in the present example, a total of five feedthroughs 157 are provided. As described above, the respective feedthroughs 157 are electrically connected to the electrode 133b.

One terminal 341 of each capacitor 340 is electrically connected to the connection plate 330. Therefore, one terminal 341 of each of the plurality of capacitors 340 is electrically connected to the electrode 133b. The capacitor 340 is, for example, a ceramic capacitor in which the dielectric material is strontium titanate, barium titanate, or the like.

In the present example, when the capacitors 340 are viewed from the pulse power module 310 side, half of the capacitors 340 are arranged on one side of the electrode 133b and the other half of the capacitors 340 are arranged on the other side of the electrode 133b in a direction perpendicular to the predetermined direction. Further, the half of the capacitors 340 and the other half of the capacitors 340 are arranged in parallel at equal intervals along the predetermined direction, respectively. Therefore, in the predetermined direction, the power supply terminal 320 is located at a substantially middle point between the capacitor 340 arranged at one endmost side and the capacitor 340 arranged at the other endmost side.

The other terminal 342 of each capacitor 340 is electrically connected to the holder 350. Therefore, the respective capacitors 340 are electrically connected in parallel. The holder 350 is a conductive frame and is electrically connected to the chamber 131 as described above. Therefore, the other terminal 342 of each capacitor 340 is electrically connected to the electrode 133a via the holder 350, the chamber 131, and the like.

A pair of conductive connection members 360 are connected to the holder 350, and the holder 350 and the connection members 360 are electrically connected to each other. Therefore, the connection members 360 are electrically connected to the other terminal 342 of the capacitor 340 via the holder 350. One connection member 360 is located on the other terminal 342 side of the half of the capacitors 340, and the other connection member 360 is located on the other terminal 342 side of the other half of the capacitors 340. The connection members 360 are plate-shaped members extending in the predetermined direction along the plurality of capacitors 340 arranged in parallel. In the present example, the longitudinal direction of the connection members 360 extends in the predetermined direction, and the in-plane direction of the connection members 360 is perpendicular to the predetermined direction and the direction in which the electrodes 133a, 133b face each other. A portion of the connection members 360 on the side connected to the holder 350, that is, the side electrically connected to the other terminal 342 of the capacitor 340, and a portion that is separated in the direction perpendicular to the predetermined direction are connected to ground terminals 390.

The ground terminals 390 are terminals of the pulse power module 310 connected to the ground. In the present example, three ground terminals 390 are connected to each of the connection members 360. In FIG. 2, the ground terminals 390 are omitted.

As shown in FIG. 4, the preionization inner electrode 183 is electrically connected to the connection plates 330 via the preionization capacitor 188, and the preionization outer electrode 185 is connected to the ground.

2.2 Operation

Next, operation of the gas laser device 100 of the comparative example will be described.

Before the gas laser device 100 outputs the laser light, the internal spaces of the optical path pipes 147a, 171, 500 and the internal spaces of the housings 145a, 161 are filled with a purge gas from the purge gas supply source (not shown). Further, a laser gas is supplied to the internal space of the chamber 131 from the laser gas supply source (not shown). When the laser gas is supplied, the laser device processor 190 controls the motor 149a to rotate the cross flow fan 149. By the rotation of the cross flow fan 149, the laser gas circulates through the internal space of the chamber 131.

Before the gas laser device 100 outputs the laser light, the laser device processor 190 receives a signal indicating the target energy Et and the signal indicating the light emission trigger Tr from the exposure apparatus processor 230. Upon receiving the signal indicating the target energy Et, the laser device processor 190 closes the shutter 170 and drives the charger 141. Further, the laser device processor 190 turns on the switch 301 of the pulse power module 310. As a result, the current from the charger 141 is charged to the capacitors 340 via the power supply terminal 320 and the connection plate 330. At this time, the current flows from a capacitor (not shown) in the pulse power module 310 to the capacitors 340, and the capacitors 340 are charged to a high potential in a short time. Then, a pulse high voltage is applied from the capacitors 340 to the electrode 133b via the feedthroughs 157 for a short time. Here, the timing at which the high voltage is applied between the preionization inner electrode 183 and the preionization outer electrode 185 is slightly earlier than the timing at which the high voltage is applied between the electrode 133a and the electrode 133b. When the high voltage is applied between the preionization inner electrode 183 and the preionization outer electrode 185, corona discharge occurs in the vicinity of the dielectric pipe 181 and an end portion of the preionization outer electrode 185, and ultraviolet light is emitted. When the laser gas between the electrode 133a and the 133b electrode is irradiated with the ultraviolet light, the laser gas between the electrode 133a and the electrode 133b undergoes preionization. After the preionization, when the high voltage is applied between the electrode 133a and the electrode 133b as described above, main discharge occurs between the electrode 133a and the electrode 133b. The main discharge is glow discharge.

By the main discharge, laser medium contained in the laser gas between the electrode 133a and the electrode 133b is brought into an excited state, and light is emitted when the laser medium returns to the ground state. The light resonates between the grating 145c and the output coupling mirror 147, and is amplified every time it passes through the discharge space at the internal space of the chamber 131, thereby causing laser oscillation. A part of the oscillated laser light is transmitted through the output coupling mirror 147 as pulse laser light and travels to the beam splitter 163.

A part of the laser light traveling to the beam splitter 163 is reflected by the beam splitter 163 and received by the optical sensor 165. The optical sensor 165 measures the energy E of the received laser light, and outputs a signal indicating the energy E to the laser device processor 190. The laser device processor 190 controls the charge voltage so that the difference ΔE between the energy E and the target energy Et falls within the allowable range, and after the difference ΔE falls within the allowable range, the laser device processor 190 transmits, to the exposure apparatus processor 230, the reception preparation completion signal indicating that reception preparation of the light emission trigger Tr is completed.

Upon receiving the reception preparation completion signal, the exposure apparatus processor 230 transmits the light emission trigger Tr to the laser device processor 190. When the laser device processor 190 opens the shutter 170 in synchronization with the reception of the light emission trigger Tr, the laser light that has passed through the shutter 170 enters the exposure apparatus 200. The laser light is, for example, pulse laser light having a center wavelength of about 193 nm.

2.3 Problem

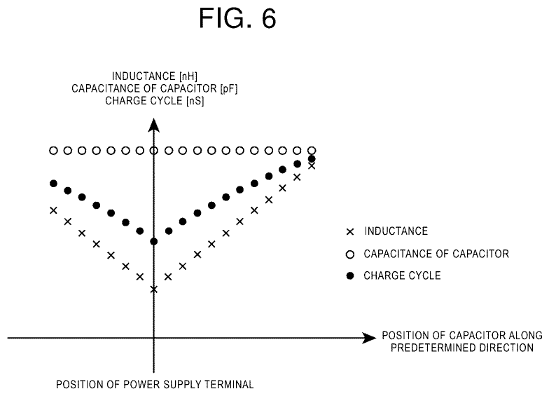

FIG. 6 is a graph showing the relationship between the distance from the power supply terminal 320 to each capacitor 340, the capacitance of each capacitor 340, the charge cycle of each capacitor 340, and the inductance of each circuit. In the present example, all of the capacitors 340 have the same capacitance. Further, since the plurality of capacitors 340 are arranged in parallel in the predetermined direction, the distance from the power supply terminal 320 to each capacitor 340 is not constant. Therefore, the circuit including the capacitor 340 having a larger distance from the power supply terminal 320 has a larger inductance. Therefore, the capacitor 340 having a larger distance from the power supply terminal 320 has a longer charge cycle. Here, the inductance may be an inductance of a loop circuit including the capacitor 340 or an inductance in a ground path of the loop circuit including the capacitor 340. Alternatively, the inductance may be an inductance in a charge loop from a capacitor (not shown) arranged in the pulse power module 310 to the capacitor 340.

By the way, it is known that an end portion of the electrode 133b, which is a cathode, in the longitudinal direction tends to wear more than the vicinity of the center. Thus, when the wear of the cathode is not constant along the longitudinal direction, stable laser light may not be output in some cases. The wear is considered to be caused by occurrence of more arc discharge between the electrodes 133a, 133b at the end portions of the electrodes 133a, 133b than in the vicinity of the center. The cause is considered to be due to the fact that a breakdown voltage at the end portions of the electrodes 133a, 133b is higher than that in the vicinity of the center, and the breakdown voltage correlates with the charge cycle of each capacitor 340. Therefore, if the charge cycle of the capacitor 340 can be made uniform regardless of the distance from the power supply terminal 320, it is considered that arc discharge at the end portions of the electrodes 133a, 133b is reduced and the non-uniformity of the wear of the cathode in the longitudinal direction is suppressed. To improve the uniformity of the charge cycle of the capacitor 340, a technology of uniformizing the inductance of the circuit including the capacitor 340 regardless of the distance from the power supply terminal 320 has been required.

Therefore, in the following embodiments, the gas laser device 100 in which non-uniformity of wear in the longitudinal direction of the cathode can be suppressed is exemplified.

3. Description of gas laser device of first embodiment

Next, the gas laser device 100 of an embodiment will be described. Any component same as that described above is denoted by an identical reference sign, and duplicate description thereof is omitted unless specific description is needed. Further, in some drawings, a part of a member may be omitted or simplified for easy viewing.

3.1 Configuration

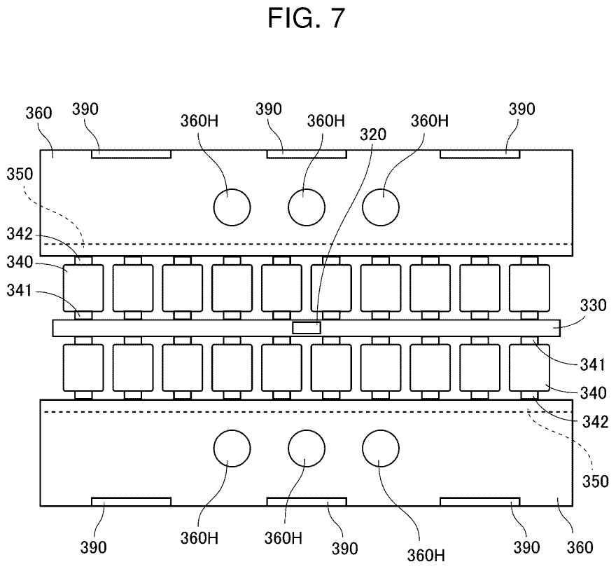

FIG. 7 is a view showing the circuit of the present embodiment connected to the pulse power module 310 in the same manner as in FIG. 5. As shown in FIG. 7, the gas laser device 100 of the present embodiment differs from the gas laser device 100 of the comparative embodiment in that a plurality of openings 360H are formed in the connection members 360. In the following drawings, for the openings 360H having the same shape and the same size, some of the openings 360H may be denoted by reference numerals, and other openings 360H may not be denoted by reference numerals. In FIG. 7, three openings 360H are formed in each of the pair of connection members 360.

In the present embodiment, each opening 360H has the same size and the same shape, and the shape is circular. The plurality of openings 360H are arranged side by side at equal intervals along the predetermined direction. The openings 360H are formed in the vicinity of the center in the longitudinal direction of the connection members 360. Specifically, the openings 360H are formed in a region in which the distance from the power supply terminal 320 in the predetermined direction is smaller than a predetermined distance, and are not formed in a region in which the distance from the power supply terminal 320 is equal to or larger than the predetermined distance. Therefore, the porosity due to the openings 360H in the close region of the connection members 360 in which the distance from the power supply terminal 320 in the predetermined direction is smaller than the predetermined distance is larger than the porosity due to the openings 360H in the region of the connection members 360 in which the distance from the power supply terminal 320 in the predetermined direction is equal to or larger than the predetermined distance. In the present embodiment, similarly to the comparative example, the number of the power supply terminals 320 is one, and the power supply terminal 320 is located at a substantially middle point between the capacitor 340 arranged at one endmost side and the capacitor 340 arranged at the other endmost side in the predetermined direction. Therefore, the porosity is larger in the region of the connection members 360 in which the distance from the midpoint is smaller than the predetermined distance than in the region in which the distance from the middle point is equal to or larger than the predetermined distance.

By forming the openings 360H as described above, it is possible to increase the inductance caused by the connection members 360 in the region in which the distance from the power supply terminal 320 in the predetermined direction is smaller than the predetermined distance. Since the plurality of openings 360H are thus formed in the connection members 360, the connection members 360 make the distribution of the inductance due to the distance between the power supply terminal 320 and the one terminal 341 of each capacitor 340 close to be uniform as compared to the case in which the plurality of openings 360H are not formed in the connection members 360. Accordingly, the connection members 360 of the present embodiment include an inductance compensation structure that makes the distribution of the inductance due to the distance between the power supply terminal 320 and the one terminal 341 of each capacitor 340 close to be uniform. The inductance compensation structure is a structure which causes the inductance in the region of the connection members 360 close to the power supply terminal 320 to be larger than that in the region far from the power supply terminal 320, and includes the plurality of openings 360H in the present embodiment. Here, the predetermined distance may be a distance that is set so that a substantial effect can be obtained by the inductance compensation structure, and may be a distance that is appropriately set according to the structure and performance of each laser oscillator.

3.2 Effect

In the chamber device CH of the present embodiment, as described above, the connection members 360 include the inductance compensation structure that makes the distribution of inductance due to the distance between the power supply terminal 320 and the one terminal 341 of each capacitor 340 close to be uniform. Therefore, the inductance of the circuit passing through each capacitor 340 becomes close to be uniform. That is, the valley of the inductance shown in FIG. 6 can be reduced. Therefore, compared to the case in which the connection members 360 do not include the inductance compensation structure, the cycles in which the respective capacitors 340 are charged may become close to be uniform. That is, the valley of the charge cycle shown in FIG. 6 may be reduced. Therefore, the breakdown voltage of the electrodes 133a, 133b can be made close to uniform in the longitudinal direction, and arc discharge generated between the electrodes 133a, 133b can be made close to be uniform. Therefore, in the chamber device CH of the present embodiment, the wear of the cathode can be made close to be uniform in the longitudinal direction. Therefore, the chamber device CH of the present embodiment may have a long lifetime.

Here, the inductance compensation structure preferably makes the distribution of the inductance close to be uniform so that the inductance from the pulse power module 310 to the capacitors 340 at the positions of the respective capacitors 340 fall within +15% of the average value of the inductance. When the inductance is uniform in such a range, the wear of the electrode 133b in the longitudinal direction can be made more uniform.

Further, in the present embodiment, three openings 360H are formed in each of the connection members 360 side by side in the predetermined direction. However, the aligning direction, the number, and the forming positions of the openings 360H are not limited to those described above as long as the distribution of the inductance due to the distance between the power supply terminal 320 and the one terminal 341 of each capacitor 340 is made close to be uniform by forming the openings 360H as compared to the case in which the openings 360H are not formed. Therefore, the number of the openings 360H may be one, or may be four or more.

In the following, modifications of the present embodiment will be described. In the following modifications, any component same as that in the first embodiment is denoted by an identical reference sign, and duplicate description thereof is omitted unless specific description is needed. Further, in some drawings, a part of a member may be omitted or simplified for easy viewing.

3.3 First modification

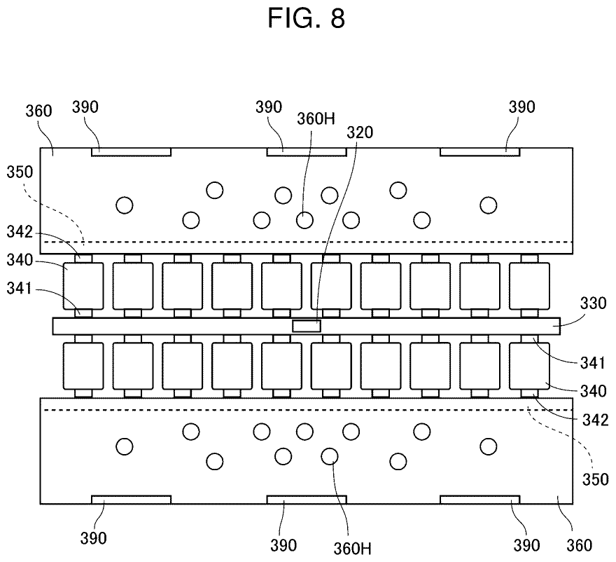

FIG. 8 is a view showing the circuit of the present modification connected to the pulse power module 310 in the same manner as in FIG. 5. The chamber device CH of the present modification mainly differs from the chamber device CH of the first embodiment in that the size of the openings 360H is smaller than the size of the openings 360H of the first embodiment, and the openings 360H are not formed at equal intervals.

In the present modification, the sizes and shapes of the respective openings 360H are the same, and the larger the distance from the power supply terminal 320 in the predetermined direction is, the larger the distance between adjacent openings 360H is. Therefore, the density of the openings 360H is larger in the region of the connection members 360 in which the distance from the power supply terminal 320 in the predetermined direction is smaller than a predetermined distance than in the region of the connection members 360 in which the distance from the power supply terminal 320 in the predetermined direction is equal to or larger than the predetermined distance. As described above, the number of the power supply terminal 320 is one, and the power supply terminal 320 is located at a substantially middle point between the capacitor 340 arranged at one endmost side and the capacitor 340 arranged at the other endmost side in the predetermined direction. Therefore, the density of the openings 360H in the region close to the middle point is larger than the density of the openings 360H in the region far from the middle point. Therefore, the porosity due to the openings 360H is larger as being closer to the middle point in the predetermined direction. With such a configuration, the connection members 360 make the distribution of the inductance due to the distance between the power supply terminal 320 and the one terminal 341 of each capacitor 340 close to be uniform as compared to the case in which the plurality of openings 360H are not formed in the connection members 360. Thus, the inductance compensation structure of the present modification includes the plurality of openings 360H having the same size formed with the above-described densities.

According to the present modification, by adjusting the position and the number of the openings 360H, the distribution of the inductance can be adjusted.

In the present modification, the size of the openings 360H may not be constant as long as the distribution of the inductance due to the distance between the power supply terminal 320 and the one terminal 341 of each capacitor 340 is made closer to be uniform than when the openings 360H are not formed. Further, as long as an arrangement in which the distance between adjacent openings 360H increases as the distance from the power supply terminal 320 in the predetermined direction increases is included, the distance between all openings 360H need not be in this arrangement.

3.4 Second modification

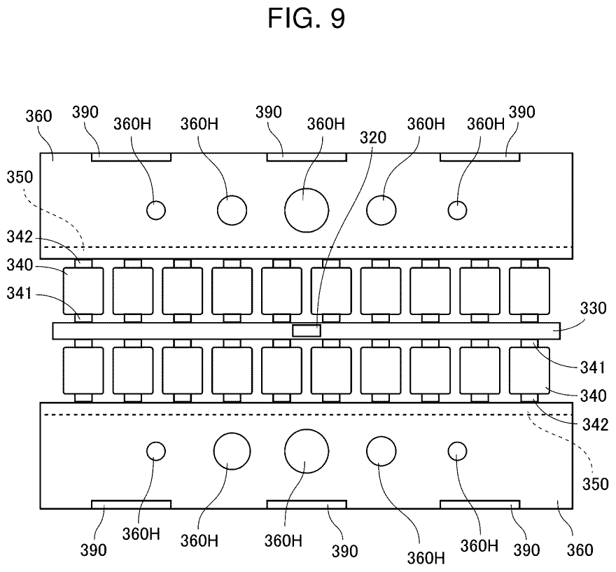

FIG. 9 is a view showing the circuit of the present modification connected to the pulse power module 310 in the same manner as in FIG. 5. The chamber device CH of the present modification mainly differs from the chamber device CH of the first embodiment in that the sizes of the plurality of openings 360H are not the same.

In the present modification, the openings 360H are formed side by side at equal intervals along the predetermined direction. Therefore, the openings 360H are formed in the connection members 360 at positions different from each other in the predetermined direction. In the present modification, the openings 360H become smaller as the distance from the power supply terminal 320 in the predetermined direction becomes larger. Therefore, in the present modification, the openings 360H formed in the region of the connection members 360 in which the distance from the power supply terminal 320 in the predetermined direction is smaller than a predetermined distance are larger than the openings 360H formed in the region of the connection members 360 in which the distance from the power supply terminal 320 in the predetermined direction is equal to or larger than the predetermined distance. As described above, the number of the power supply terminal 320 is one, and the power supply terminal 320 is located at a substantially middle point between the capacitor 340 arranged at one endmost side and the capacitor 340 arranged at the other endmost side in the predetermined direction. Therefore, the openings 360H in the region close to the middle point are larger than the openings 360H in the region far from the middle point. Therefore, the porosity due to the openings 360H is larger as being closer to the middle point in the predetermined direction. With such a configuration, the connection members 360 make the distribution of the inductance due to the distance between the power supply terminal 320 and the one terminal 341 of each capacitor 340 close to be uniform as compared to the case in which the plurality of openings 360H are not formed in the connection members 360. Therefore, the inductance compensation structure of the present modification includes the plurality of openings 360H having different sizes and formed in the connection members 360 at different positions in the predetermined direction as described above.

According to the present modification, by adjusting the position and the size of the openings 360H, the distribution of the inductance can be adjusted.

In the present modification, the openings 360H may not be formed at equal intervals as long as the distribution of the inductance due to the distance between the power supply terminal 320 and the one terminal 341 of each capacitor 340 is made closer to be uniform than when the openings 360H are not formed.

3.5 Third modification

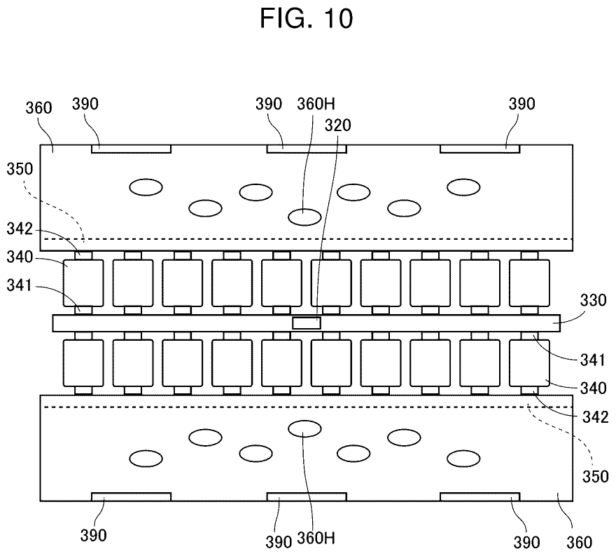

FIG. 10 is a view showing the circuit of the present modification connected to the pulse power module 310 in the same manner as in FIG. 5. The chamber device CH of the present modification mainly differs from the chamber device CH of the first embodiment in that the plurality of openings 360H are not circular.

In the present modification, each of the openings 360H is generally elliptical and have a major axis along the predetermined direction. In the present modification, similarly to the first modification, the density of the openings 360H is larger in the region of the connection members 360 in which the distance from the power supply terminal 320 in the predetermined direction is smaller than a predetermined distance than in the region of the connection members 360 in which the distance from the power supply terminal 320 in the predetermined direction is equal to or larger than the predetermined distance. Thus, the inductance compensation structure of the present modification includes the plurality of ellipse openings 360H formed with the above-described densities.

According to the present modification, similar effects as those of the embodiment and the modification thereof described with reference to FIGS. 7 and 8 can be obtained.

In the present modification, the major axis of the openings 360H may not be along the predetermined direction and may be, for example, along the direction perpendicular to the predetermined direction as long as the distribution of the inductance due to the distance between the power supply terminal 320 and the one terminal 341 of each capacitor 340 is made closer to be uniform than when the openings 360H are not formed. Further, as long as the distribution of the inductance is made close to be uniform as described above, the shapes of the openings 360H are not limited to ellipses, and may be other shapes that are same to each other. Examples of such shapes include triangles, quadrangles, and racetrack shapes.

3.6 Fourth modification

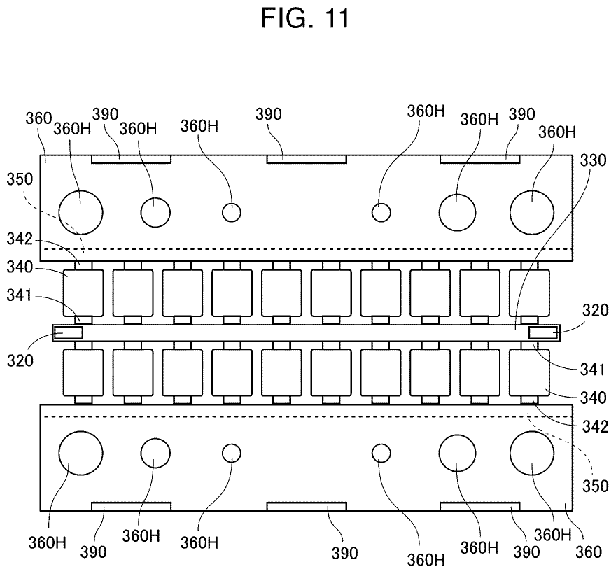

FIG. 11 is a view showing the circuit of the present modification connected to the pulse power module 310 in the same manner as in FIG. 5. The chamber device CH of the present modification mainly differs from the chamber device CH of the first embodiment in that the number of the power supply terminals 320 is two and the sizes of the plurality of openings 360H are not the same.

The power supply terminals 320 of the present modification are connected respectively to both ends of the connection plate 330 in the longitudinal direction. In the present modification, similarly to the second modification, the openings 360H are formed at equal intervals along the predetermined direction, and the openings 360H become smaller as the distance from the power supply terminal 320 in the predetermined direction becomes larger. Therefore, in the present modification, the openings 360H are smaller as being closer to the substantial middle point between the capacitor 340 arranged at one endmost side and the capacitor 340 arranged at the other endmost side in the predetermined direction. With such a configuration, the connection members 360 make the distribution of the inductance due to the distance between the power supply terminal 320 and the one terminal 341 of each capacitor 340 close to be uniform as compared to the case in which the plurality of openings 360H are not formed in the connection members 360. Therefore, the inductance compensation structure of the present modification includes the plurality of openings 360H having different sizes and formed in the connection members 360 at different positions in the predetermined direction as described above.

According to the present modification, even when a plurality of the power supply terminals 320 are provided, the distribution of the inductance can be adjusted by adjusting the positions and sizes of the openings 360H.

In the present modification, the openings 360H may not be formed at equal intervals as long as the distribution of the inductance due to the distance between the power supply terminal 320 and the one terminal 341 of each capacitor 340 is made closer to be uniform than when the openings 360H are not formed.

Further, the number of the power supply terminals 320 may be three or more. However, it is preferable that the number of the power supply terminals 320 is smaller than the number of the capacitors 340 parallel to each other in the predetermined direction. Even in this case, the openings 360H become smaller as the distance from the power supply terminal 320 in the predetermined direction becomes larger.

Further, when the case in which two power supply terminals 320 are provided as in the present modification is applied to the first modification, the density of the openings 360H is smaller as being closer to the substantial middle point between the capacitor 340 arranged at one endmost side and the capacitor 340 arranged at the other endmost side in the predetermined direction. With such a configuration, the connection members 360 make the distribution of the inductance due to the distance between the power supply terminal 320 and the one terminal 341 of each capacitor 340 close to be uniform as compared to the case in which the plurality of openings 360H are not formed in the connection members 360. Further, even when the number of the power supply terminals 320 is three or more, the density of the openings 360H becomes smaller as the distance from the power supply terminal 320 in the predetermined direction becomes larger.

3.7 Fifth modification

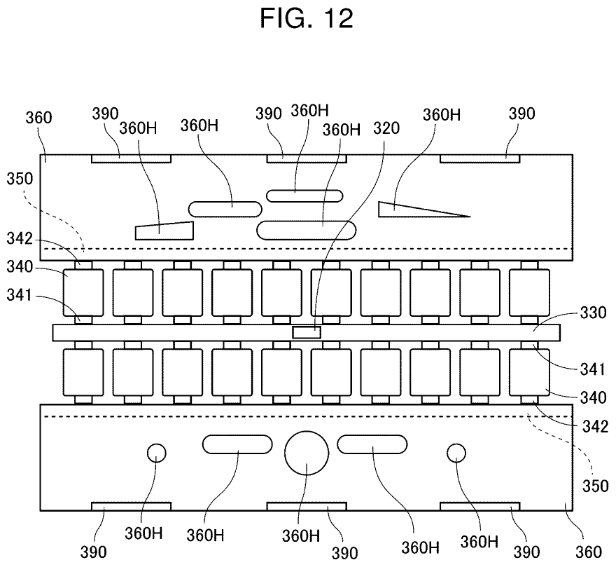

FIG. 12 is a view showing the circuit of the present modification connected to the pulse power module 310 in the same manner as in FIG. 5. The chamber device CH of the present modification mainly differs from the chamber device CH of the first embodiment in that the shapes of the plurality of openings 360H are not constant.

In the present modification, the inductance compensation structure includes the openings 360H having mutually different shapes. In the present modification, the openings 360H have circular shapes, polygonal shapes such as triangles and squares, and racetrack shapes. The openings 360H having the plurality of shapes make the distribution of the inductance due to the distance between the power supply terminal 320 and the one terminal 341 of each capacitor 340 closer to be uniform than when the openings 360H are not formed.

According to the present modification, by adjusting the shapes of the openings 360H, the distribution of the inductance can be adjusted.

Here, the shapes of the openings 360H are not limited to those described above as long as the distribution of the inductance due to the distance between the power supply terminal 320 and the one terminal 341 of each capacitor 340 is made close to be uniform as compared to the case in which the openings 360H are not formed.

3.8 Sixth modification

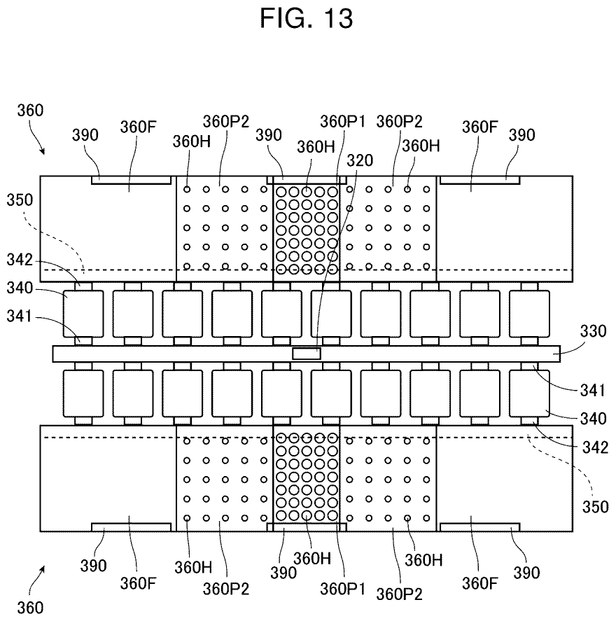

FIG. 13 is a view showing the circuit of the present modification connected to the pulse power module 310 in the same manner as in FIG. 5. The chamber device CH of the present modification mainly differs from the chamber device CH of the first embodiment in that the connection members 360 include a plurality of punching metals 360P1, 360P2, arranged along a predetermined direction, whose densities of the openings 360H are different from each other.

In the present modification, the connection members 360 include the punching metal 360P1, the punching metals 360P2, and conductive plate members 360F in which no opening is formed, respectively, and the punching metal 360P1, the punching metals 360P2, and the conductive plate members 360F are connected to the holder 350 and the ground terminal 390, respectively. The punching metal 360P1 is arranged at a position closest to the power supply terminal 320, the punching metals 360P2 are arranged at positions farther from the power supply terminal 320 than the punching metal 360P1, and the conductive plate members 360F are arranged at positions farther from the power supply terminal 320 than the punching metals 360P2. In the present modification, the punching metal 360P1 and the punching metals 360P2 are connected to each other, and the punching metals 360P2 and the conductive plate members 360F are connected to each other.

The openings 360H formed in the punching metal 360P1 are larger than the openings 360H formed in the punching metals 360P2. The density of the plurality of openings 360H formed in the punching metal 360P1 is larger than the density of the plurality of openings 360H formed in the punching metals 360P2. Therefore, in the present modification, the openings 360H formed in the region of the connection members 360 in which the distance from the power supply terminal 320 in the predetermined direction is smaller than a predetermined distance are larger than the openings 360H formed in the region of the connection members 360 in which the distance from the power supply terminal 320 in the predetermined direction is equal to or larger than the predetermined distance. Further, in the present modification, the density of the openings 360H is larger in the region of the connection members 360 in which the distance from the power supply terminal 320 in the predetermined direction is smaller than a predetermined distance than in the region of the connection members 360 in which the distance from the power supply terminal 320 in the predetermined direction is equal to or larger than the predetermined distance. With such a configuration, the connection members 360 make the distribution of the inductance due to the distance between the power supply terminal 320 and the one terminal 341 of each capacitor 340 close to be uniform as compared to the case in which the plurality of openings 360H are not formed in the connection members 360.

According to the present modification, the size and the density of the openings 360H can be changed in the predetermined direction by using the punching metals 360P1, 360P2 that are easily available in the market. Therefore, the inductance compensation structure can be easily formed.

Here, the openings 360H may be the same in either the density or the size between the punching metals 360P1, 360P2 as long as the distribution of the inductance due to the distance between the power supply terminal 320 and the one terminal 341 of each capacitor 340 is made closer to be uniform than when the openings 360H are not formed.

4. Description of gas laser device of second embodiment

Next, the gas laser device of a second embodiment will be described. Any component same as that described above is denoted by an identical reference sign, and duplicate description thereof is omitted unless specific description is needed.

4.1 Configuration

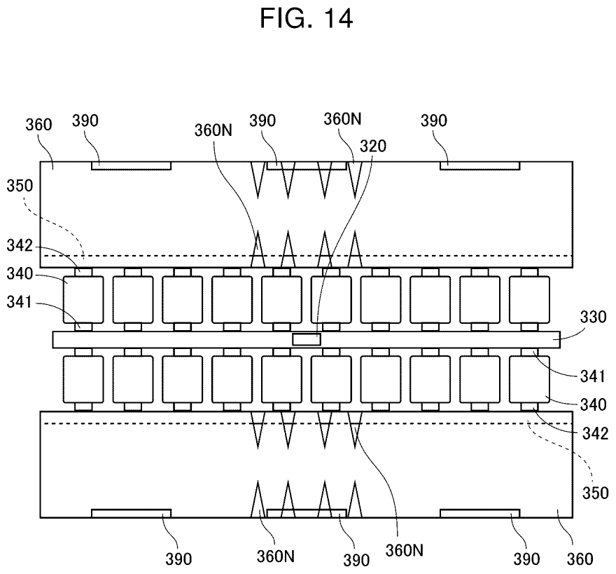

FIG. 14 is a view showing the circuit of the present embodiment connected to the pulse power module 310 in the same manner as in FIG. 5. The chamber device CH of the present embodiment mainly differs from the chamber device CH of the comparative embodiment in that the opening 360H is not formed and a plurality of notches 360N are formed in the connection members 360. In the following drawings, for the notches 360N having the same shape and the same size, some of the notches 360N may be denoted by reference numerals, and other notches 360N may not be denoted by reference numerals.

In the present embodiment, each notch 360N has the same size and the same shape, and is generally V-shaped. The plurality of notches 360N are formed side by side at equal intervals along the predetermined direction. Further, the notches 360N are formed on the holder 350 side and the ground terminal 390 side in the vicinity of the center of each of the pair of connection members 360 in the longitudinal direction. Specifically, the notches 360N are formed in a region in which the distance from the power supply terminal 320 in the predetermined direction is smaller than a predetermined distance, and are not formed in a region in which the distance from the power supply terminal 320 is larger than the predetermined distance. Therefore, the porosity due to the notches 360N in the close region of the connection members 360 in which the distance from the power supply terminal 320 in the predetermined direction is smaller than the predetermined distance is larger than the porosity due to the notches 360N in the region of the connection members 360 in which the distance from the power supply terminal 320 in the predetermined direction is equal to or larger than the predetermined distance. Here, the opening area in the present embodiment is the area of the notches 360N. In the present embodiment, similarly to the comparative example, the number of the power supply terminals 320 is one, and the power supply terminal 320 is located at a substantially middle point between the capacitor 340 arranged at one endmost side and the capacitor 340 arranged at the other endmost side in the predetermined direction. Therefore, the porosity is larger in the region in which the distance from the midpoint is smaller than the predetermined distance than in the region in which the distance from the middle point is equal to or larger than the predetermined distance.

By forming the notches 360N as described above, it is possible to increase the inductance due to the connection members 360 in the region in which the distance from the power supply terminal 320 in the predetermined direction is smaller than the predetermined distance. Since the plurality of notches 360N are thus formed in the connection members 360, the connection members 360 make the distribution of the inductance due to the distance between the power supply terminal 320 and the one terminal 341 of each capacitor 340 close to be uniform as compared to the case in which the plurality of notches 360N are not formed in the connection members 360. Accordingly, the connection members 360 of the present embodiment include an inductance compensation structure that makes the distribution of the inductance due to the distance between the power supply terminal 320 and the one terminal 341 of each capacitor 340 close to be uniform. The inductance compensation structure is a structure in which the inductance in the region of the connection member 360 close to the power supply terminal 320 is larger than that in the region far from the power supply terminal 320, and includes the plurality of notches 360N in the present embodiment.

4.2 Effect

The chamber device CH of the present embodiment includes the inductance compensation structure described above. Therefore, similarly to the first embodiment, the wear of the cathode can be made close to be uniform in the longitudinal direction, and the chamber device CH may have a long lifetime. Further, since the inductance compensation structure can be configured by the notches 360N, the distribution of the inductance due to the distance between the capacitor 340 and the one terminal 341 can be easily made uniform.

Here, in the present embodiment, four notches 360N are formed in each of the connection members 360 side by side in the predetermined direction. However, the number and the forming position of the notches 360N are not limited to those described above as long as the distribution of the inductance due to the distance between the power supply terminal 320 and the one terminal 341 of each capacitor 340 is made close to be uniform by forming the notches 360N as compared to the case in which the notches 360N are not formed. Therefore, the number of the notches 360N may be one, or may be five or more.

Further, in the present embodiment, the notches 360N are formed at the connection members 360 on both of the holder 350 side and the ground terminal 390 side. However, the notches 360N may be formed at the connection members 360 only on one of the holder 350 side and the ground terminal 390 side.

In the following, modifications of the present embodiment will be described. In the following modifications, any component same as that in the second embodiment is denoted by an identical reference sign, and duplicate description thereof is omitted unless specific description is needed. Further, in some drawings, a part of a member may be omitted or simplified for easy viewing.

4.3 First modification

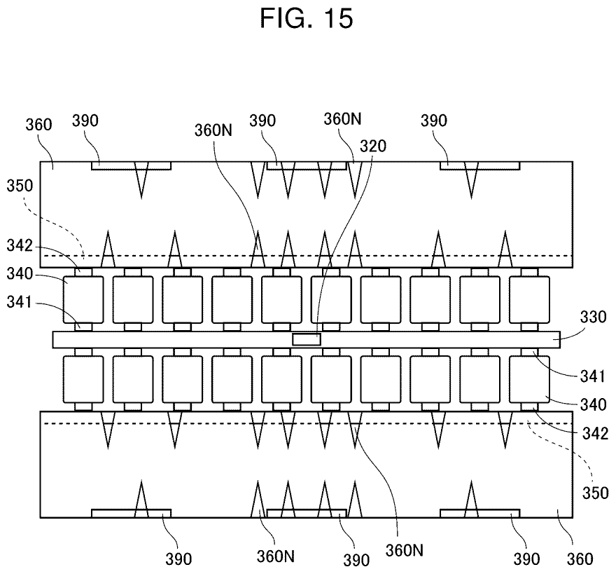

FIG. 15 is a view showing the circuit of the present modification connected to the pulse power module 310 in the same manner as in FIG. 5. The chamber device CH of the present modification mainly differs from the chamber device CH of the second embodiment in that the notches 360N are not formed at equal intervals.

In the present modification, the sizes and shapes of the respective notches 360N are the same, and the larger the distance from the power supply terminal 320 in the predetermined direction is, the larger the distance between adjacent notches 360N is. Therefore, the density of the notches 360N is larger in the region of the connection members 360 in which the distance from the power supply terminal 320 in the predetermined direction is smaller than a predetermined distance than in the region of the connection members 360 in which the distance from the power supply terminal 320 in the predetermined direction is equal to or larger than the predetermined distance. As described above, the number of the power supply terminal 320 is one, and the power supply terminal 320 is located at a substantially middle point between the capacitor 340 arranged at one endmost side and the capacitor 340 arranged at the other endmost side in the predetermined direction. Therefore, the density of the notches 360N in the region close to the middle point is larger than the density of the notches 360N in the region far from the middle point. Therefore, the porosity due to the notches 360N is larger as being closer to the middle point in the predetermined direction. With such a configuration, the connection members 360 make the distribution of the inductance due to the distance between the power supply terminal 320 and the one terminal 341 of each capacitor 340 close to be uniform as compared to the case in which the plurality of notches 360N are not formed in the connection members 360. Thus, the inductance compensation structure of the present modification includes the plurality of notches 360N having the same size formed with the above-described densities.

According to the present modification, by adjusting the position and the number of the notches 360N, the distribution of the inductance can be adjusted.

In the present modification, the size of the notches 360N may not be constant as long as the distribution of the inductance due to the distance between the power supply terminal 320 and the one terminal 341 of each capacitor 340 is made closer to be uniform than when the notches 360N are not formed.

4.4 Second modification

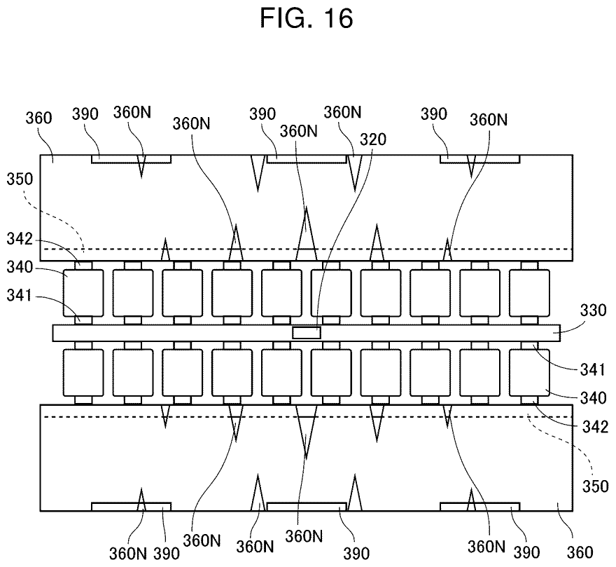

FIG. 16 is a view showing the circuit of the present modification connected to the pulse power module 310 in the same manner as in FIG. 5. The chamber device CH of the present modification mainly differs from the chamber device CH of the second embodiment in that the sizes of the plurality of notches 360N are not the same.

In the present modification, the notches 360N are formed side by side at equal intervals along the predetermined direction. Therefore, the notches 360N are formed in the connection members 360 at positions different from each other in the predetermined direction. In the present modification, the size of the notch 360N becomes smaller as the distance from the power supply terminal 320 in the predetermined direction becomes larger. Therefore, in the present modification, the notches 360N formed in the region of the connection members 360 in which the distance from the power supply terminal 320 in the predetermined direction is smaller than a predetermined distance are larger than the notches 360N formed in the region of the connection members 360 in which the distance from the power supply terminal 320 in the predetermined direction is equal to or larger than the predetermined distance. As described above, the number of the power supply terminal 320 is one, and the power supply terminal 320 is located at a substantially middle point between the capacitor 340 arranged at one endmost side and the capacitor 340 arranged at the other endmost side in the predetermined direction. Therefore, the notches 360N in the region close to the middle point is larger than the notches 360N in the region far from the middle point. Therefore, the porosity due to the notches 360N is larger as being closer to the middle point in the predetermined direction. With such a configuration, the connection members 360 make the distribution of the inductance due to the distance between the power supply terminal 320 and the one terminal 341 of each capacitor 340 close to be uniform as compared to the case in which the plurality of notches 360N are not formed in the connection members 360. Therefore, the inductance compensation structure of the present modification includes the plurality of notches 360N having different sizes and formed in the connection members 360 at different positions in the predetermined direction as described above.

According to the present modification, by adjusting the position and the size of the notches 360N, the distribution of the inductance can be adjusted.

In the present modification, the notches 360N may not be formed at equal intervals as long as the distribution of the inductance due to the distance between the power supply terminal 320 and the one terminal 341 of each capacitor 340 is made closer to be uniform than when the notches 360N are not formed.

4.5 Third modification

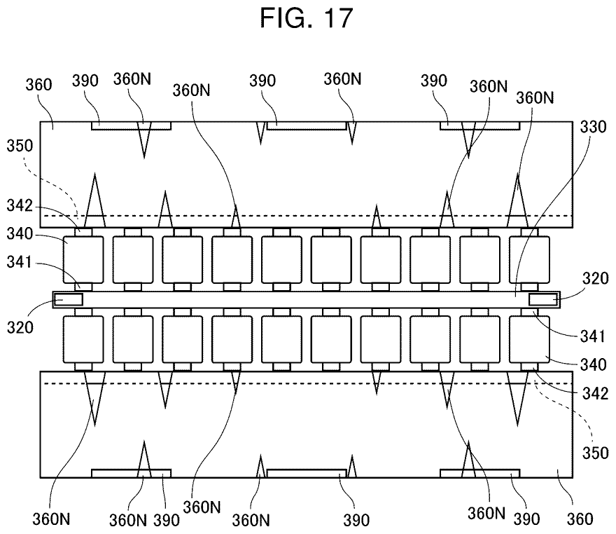

FIG. 17 is a view showing the circuit of the present modification connected to the pulse power module 310 in the same manner as in FIG. 5. The chamber device CH of the present modification mainly differs from the chamber device CH of the second embodiment in that the number of the power supply terminals 320 is two and the sizes of the plurality of notches 360N are not the same.

The power supply terminals 320 of the present modification has the similar configuration as the fourth modification of the first embodiment. In the present modification, similarly to the second modification of the second embodiment, the notches 360N are formed at equal intervals along the predetermined direction, and the size of the notch 360N becomes smaller as the distance from the power supply terminal 320 in the predetermined direction becomes larger. Therefore, in the present modification, the notches 360N are smaller as being closer to the substantial middle point between the capacitor 340 arranged at one endmost side and the capacitor 340 arranged at the other endmost side in the predetermined direction. With such a configuration, the connection members 360 make the distribution of the inductance due to the distance between the power supply terminal 320 and the one terminal 341 of each capacitor 340 close to be uniform as compared to the case in which the plurality of notches 360N are not formed in the connection members 360. Therefore, the inductance compensation structure of the present modification includes the plurality of notches 360N having different sizes and formed in the connection members 360 at different positions in the predetermined direction as described above.

According to the present modification, even when a plurality of the power supply terminals 320 are provided, the distribution of the inductance can be adjusted by adjusting the positions and sizes of the notches 360N.

In the present modification, the notches 360N may not be formed at equal intervals as long as the distribution of the inductance due to the distance between the power supply terminal 320 and the one terminal 341 of each capacitor 340 is made closer to be uniform than when the notches 360N are not formed.

Further, the number of the power supply terminals 320 may be three or more. Even in this case, in the present modification, the size of the notch 360N becomes smaller as the distance from the power supply terminal 320 in the predetermined direction becomes larger.

Further, when the case in which two power supply terminals 320 are provided as in the present modification is applied to the first modification of the second embodiment, the density of the notches 360N is smaller as being closer to the substantial middle point between the capacitor 340 arranged at the one endmost side and the capacitor 340 arranged at the other endmost side in the predetermined direction. With such a configuration, the connection members 360 make the distribution of the inductance due to the distance between the power supply terminal 320 and the one terminal 341 of each capacitor 340 close to be uniform as compared to the case in which the plurality of notches 360N are not formed in the connection members 360. Further, even when the number of the power supply terminals 320 is three or more, the density of the notches 360N becomes smaller as the distance from the power supply terminal 320 in the predetermined direction becomes larger.

4.6 Fourth modification

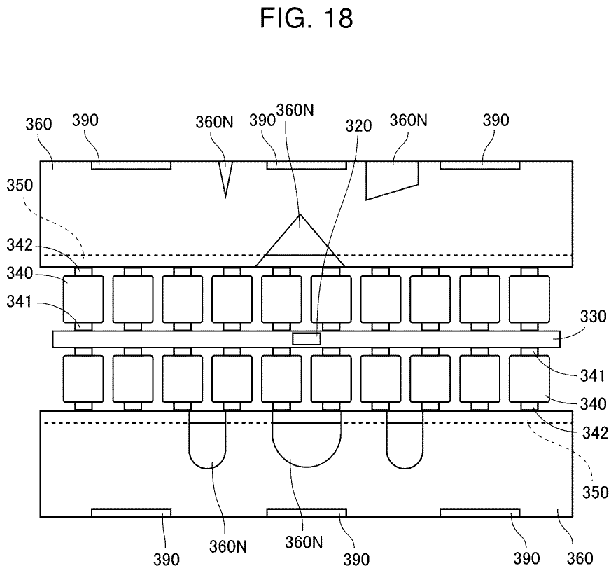

FIG. 18 is a view showing the circuit of the present modification connected to the pulse power module 310 in the same manner as in FIG. 5. The chamber device CH of the present modification mainly differs from the chamber device CH of the first embodiment in that the shapes of the plurality of notches 360N are not constant.

In the present modification, the inductance compensation structure includes the notches 360N having mutually different shapes. In the present modification, the notches 360N have polygonal shapes such as V shapes, U shapes, and squares. The notches 360N having the plurality of shapes make the distribution of the inductance due to the distance between the power supply terminal 320 and the one terminal 341 of each capacitor 340 closer to be uniform than when the notches 360N are not formed.

According to the present modification, by adjusting the shapes of the notches 360N, the distribution of the inductance can be adjusted.

Here, the shapes of the notches 360N are not limited to those described above as long as the distribution of the inductance due to the distance between the power supply terminal 320 and the one terminal 341 of each capacitor 340 is made close to be uniform as compared to the case in which the notches 360N are not formed.

5. Description of gas laser device of third embodiment

Next, the gas laser device of a third embodiment will be described. Any component same as that described above is denoted by an identical reference sign, and duplicate description thereof is omitted unless specific description is needed.

5.1 Configuration

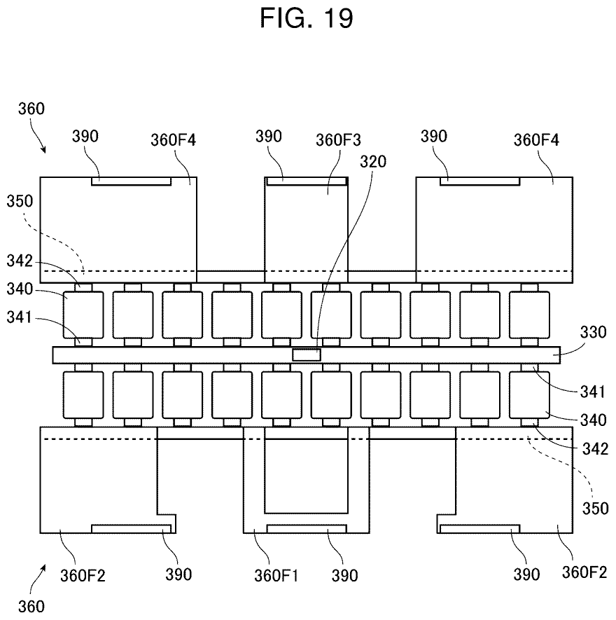

FIG. 19 is a view showing the circuit of the present embodiment connected to the pulse power module 310 in the same manner as in FIG. 5. The chamber device CH of the present embodiment mainly differs from the chamber device CH of the first and second embodiments in that one connection member 360 is configured by a plurality of conductive plate portions 360F1, 360F₂ and the other connection member 360 is configured by a plurality of conductive plate portions 360F3, 360F₄.

The plate portions 360F1, 360F₂ are arranged on one side of the power supply terminal 320 in the direction perpendicular to the predetermined direction, and the plate portions 360F3, 360F₄ are arranged on the other side of the power supply terminal 320. The plate portions 360F1, 360F₃ are arranged at positions closest to the power supply terminal 320, a pair of the plate portions 360F2 are arranged so as to sandwich the plate portion 360F1 at positions farther from the power supply terminal 320 than the plate portion 360F1, and a pair of the plate portions 360F4 are arranged so as to sandwich the plate portion 360F3 at positions farther from the power supply terminal 320 than the plate portion 360F3. The plate portion 360F1 and the respective plate portions 360F2 are spaced apart from each other, and the plate portion 360F3 and the respective plate portions 360F4 are spaced apart from each other.

The plate portions 360F1 to 360F₄ are individually connected to the holder 350 and the ground terminal 390. Here, the plate portion 360F1 is generally U-shaped and is connected to the holder 350 at two positions. Therefore, in the plate portion 360F1, the sum of widths along the predetermined direction of the two sections whose longitudinal direction is oriented to the direction perpendicular to the predetermined direction is the minimum value of a conductive width along the predetermined direction of the plate portion 360F1. The conductive width is a width of a portion through which a current can flow. The pair of plate portions 360F2 have shapes that are line-symmetric with respect to each other in the predetermined direction, and the pair of plate portions 360F4 have shapes that are line-symmetric with respect to each other in the predetermined direction. Regarding each of the plate portions 360F2 to 360F₄, the width of the portion connected to the holder 350 is the minimum value of the conductive width along the predetermined direction. The minimum value of the conductive width along the predetermined direction of the plate portion 360F1 is smaller than the conductive width along the predetermined direction of each plate portion 360F2, and the minimum value of the conductive width along the predetermined direction of the plate portion 360F3 is smaller than the conductive width along the predetermined direction of each plate portion 360F4. Therefore, the inductance of the plate portion 360F1 from the holder 350 to the ground terminal 390 is larger than the inductance of each plate portion 360F2 from the holder 350 to the ground terminal 390, and the inductance of the plate portion 360F3 from the holder 350 to the ground terminal 390 is larger than the inductance of each plate portion 360F4 from the holder 350 to the ground terminal 390. With such a configuration, the connection members 360 make the distribution of the inductance due to the distance between the power supply terminal 320 and the one terminal 341 of each capacitor 340 close to be uniform as compared to the case in which each connection member 360 is continuously formed from one end side to the other end side.

That is, in the present embodiment, the connection member 360 is made of the plurality of conductive plate portions 360F1, 360F₂ or plate portions 360F3, 360F₄ spaced from each other along the predetermined direction, the inductance compensation structure includes the plate portions 360F1, 360F₂ or the plate portions 360F3, 360F₄, and the minimum value of the conductive width of the plate portions 360F1, 360F₃, close to the power supply terminal 320, at which the distance in the predetermined direction from the power supply terminal 320 than a predetermined distance is smaller than the minimum value of the conductive width of the plate portions 360F2, 360F₄ at which the distance in the predetermined direction from the power supply terminal 320 is equal to or longer than the predetermined distance.

### 5.2 Effect

The chamber device CH of the present embodiment includes the inductance compensation structure described above. Therefore, similarly to the first embodiment, the wear of the cathode can be made close to be uniform in the longitudinal direction, and the chamber device CH may have a long lifetime. Further, according to the present embodiment, by changing the minimum value of the conductive widths of the respective plate portions 360F1 to 360F₄, the distribution of the inductance due to the distance from the one terminal 341 of the capacitor 340 can be easily made close to be uniform.

6. Description of gas laser device of fourth embodiment

Next, the gas laser device of a fourth embodiment will be described. Any component same as that described above is denoted by an identical reference sign, and duplicate description thereof is omitted unless specific description is needed.

6.1 Configuration

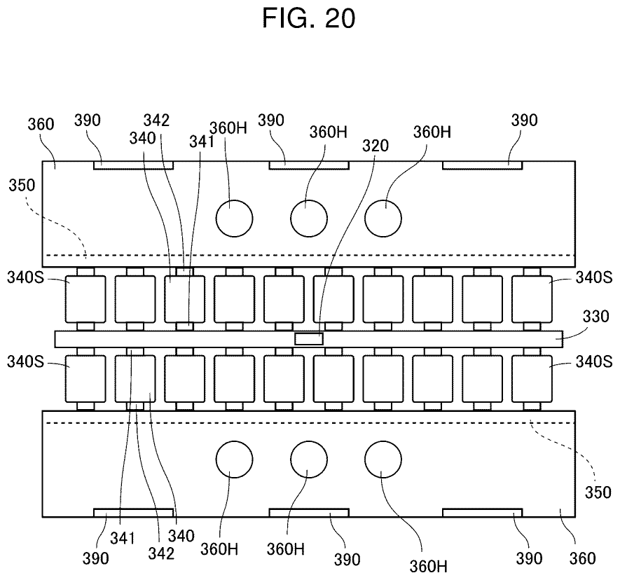

FIG. 20 is a view showing the circuit of the present embodiment connected to the pulse power module 310 in the same manner as in FIG. 5. The chamber device CH of the present embodiment mainly differs from the chamber device CH of the first embodiment in that the capacitance of capacitors 340S located at the endmost portions in the predetermined direction is smaller than the capacitance of the other capacitors 340. Therefore, when the same voltage is applied from the power supply terminal 320, the charge cycle of the capacitors 340S is shorter than that of the other capacitors 340.

6.2 Effect

In the present embodiment, the configuration of the connection members 360 is similar to that of the connection members 360 of the first embodiment. Thus, the inductance compensation structure is configured including the plurality of openings 360H. Even when the connection members 360 cannot make the distribution of the inductance due to the distance between the power supply terminal 320 and the one terminal 341 of each capacitor 340 completely uniform, the distribution of the inductance due to the distance between the power supply terminal 320 and the one terminal 341 of each capacitor 340 can be made closer to be uniform by changing the capacitance of the capacitors 340S.

Here, FIG. 20 shows an example in which the capacitance of the capacitors 340S located at the endmost portions in the predetermined direction is smaller than the capacitance of the other capacitors 340. However, the present embodiment is not limited thereto, and the capacitance of the capacitors 340S arranged at positions between each endmost portion and a predetermined position in the predetermined direction may be smaller than the capacitance of the other capacitors 340. For example, two or three capacitors 340 at the endmost portion side in the predetermined direction may have the capacitance reduced and set as the capacitors 340S, and the capacitance of the other capacitors 340 may not be changed. That is, in the present embodiment, the capacitance of the capacitors 340S arranged at positions at which the distance from the power supply terminal 320 in the predetermined direction equal to or longer than the predetermined distance is smaller than the capacitance of the capacitors 340 arranged at close positions at which the distance from the power supply terminal 320 in the predetermined direction is smaller than the predetermined distance, as long as the distribution of the inductance due to the distance between the power supply terminal 320 and the one terminal 341 of each capacitor 340 is made close to be uniform.

Further, the configuration in which the capacitors 340S are provided as in the present embodiment may be applied to the modifications of the first embodiment, the second embodiment and the modifications thereof, and the third embodiment.

7. Description of gas laser device of fifth embodiment

Next, the gas laser device of a fifth embodiment will be described. Any component same as that described above is denoted by an identical reference sign, and duplicate description thereof is omitted unless specific description is needed.

7.1 Configuration

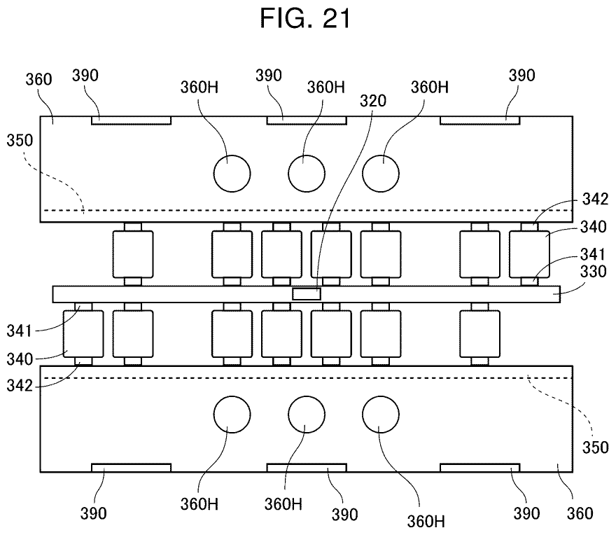

FIG. 21 is a view showing the circuit of the present embodiment connected to the pulse power module 310 in the same manner as in FIG. 5. In the chamber device CH of the present embodiment, the capacitors 340 arranged in the vicinity of the power supply terminal 320 are arranged at equal intervals along the predetermined direction in a similar manner as in the first embodiment, but the interval between the capacitors 340 arranged at positions away from the power supply terminal 320 is larger than the interval between the capacitors 340 arranged in the vicinity of the power supply terminal 320. That is, in the present embodiment, the density of the capacitors 340 arranged at positions at which the distance from the power supply terminal 320 in the predetermined direction is equal to or larger than the predetermined distance is smaller than the density of the capacitors 340 arranged at close positions at which the distance from the power supply terminal 320 in the predetermined direction is smaller than the predetermined distance.

7.2 Effect

In the present embodiment, the configuration of the connection members 360 is similar to that of the connection members 360 of the first embodiment. Thus, the inductance compensation structure is configured including the plurality of openings 360H. Even when the connection members 360 cannot make the distribution of the inductance due to the distance between the power supply terminal 320 and the one terminal 341 of each capacitor 340 completely uniform, the distribution of the inductance due to the distance between the power supply terminal 320 and the one terminal 341 of each capacitor 340 can be made closer to be uniform by reducing the density of the capacitors 340 arranged at positions at which the distance from the power supply terminal 320 in the predetermined direction is equal to or larger than a predetermined direction.

Here, the configuration in which the capacitors 340 are provided as in the present embodiment may be applied to the modifications of the first embodiment, the second embodiment and the modifications thereof, the third embodiment, and the fourth embodiment.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A chamber device comprising:
a pair of discharge electrodes arranged with a longitudinal direction thereof oriented along a predetermined direction as being apart from and facing each other;
a chamber having an internal space at which the pair of discharge electrodes are arranged and a laser gas is enclosed;
a plurality of capacitors arranged in parallel along the predetermined direction;
at least one power supply terminal electrically connecting one of the discharge electrodes and one terminal of each capacitor to a high-voltage power source; and
a conductive plate-shaped connection member extending in the predetermined direction along the plurality of capacitors, electrically connected to the other terminal of each capacitor, and having a portion away from a side electrically connected to the other terminal in the direction perpendicular to the predetermined direction be connected to the ground,
the connection member including an inductance compensation structure that makes a distribution of inductance due to a distance between the power supply terminal and the one terminal of each of the capacitors close to be uniform.

2. The chamber device according to claim 1,
wherein the inductance compensation structure is a structure that causes inductance in a region of the connection member close to the power supply terminal to be larger than that in a region far from the power supply terminal.

3. The chamber device according to claim 1,
wherein the inductance compensation structure includes at least one opening formed in the connection member, and
porosity due to the opening in a close region of the connection member in which the distance from the power supply terminal in the predetermined direction is smaller than a predetermined distance is larger than porosity due to the opening in a region of the connection member in which the distance from the power supply terminal in the predetermined direction is equal to or larger than the predetermined distance.

4. The chamber device according to claim 3,
wherein a number of the power supply terminal is one, and the power supply terminal is located at a substantially middle point between the capacitor arranged at one endmost side and the capacitor arranged at the other endmost side in the predetermined direction, and
the porosity is larger as being closer to the middle point in the predetermined direction.

5. The chamber device according to claim 3,
wherein the inductance compensation structure includes a plurality of the openings, and
a density of the openings formed in a region of the connection member in which the distance from the power supply terminal in the predetermined direction is smaller than a predetermined distance is larger than a density of the openings formed in a region of the connection member in which the distance from the power supply terminal in the predetermined direction is equal to or larger than the predetermined distance.

6. The chamber device according to claim 5,
wherein the connection member includes a plurality of punching metals, arranged along the predetermined direction, in which the densities of the openings are different from each other.

7. The chamber device according to claim 3,
wherein the inductance compensation structure includes a plurality of the openings formed in the connection member at different positions in the predetermined direction, and
the openings formed in a region of the connection member in which the distance from the power supply terminal in the predetermined direction is smaller than a predetermined distance is larger than the openings formed in a region of the connection member in which the distance from the power supply terminal in the predetermined direction is equal to or larger than the predetermined distance.

8. The chamber device according to claim 7,
wherein the connection member includes a plurality of punching metals, arranged along the predetermined direction, having the openings different in size for each punching metal.

9. The chamber device according to claim 3,
wherein the opening has a circular shape.

10. The chamber device according to claim 1,
wherein the inductance compensation structure includes at least one notch formed in the connection member, and
porosity due to the notch in a close region of the connection member in which the distance from the power supply terminal in the predetermined direction is smaller than a predetermined distance is larger than the porosity due to the notch in a region of the connection member in which the distance from the power supply terminal in the predetermined direction is equal to or larger than the predetermined distance.

11. The chamber device according to claim 10,
wherein a number of the power supply terminal is one, and the power supply terminal is located at a substantially middle point between the capacitor arranged at one endmost side and the capacitor arranged at the other endmost side in the predetermined direction, and
the porosity is larger as being closer to the middle point in the predetermined direction.

12. The chamber device according to claim 10,
wherein the inductance compensation structure includes a plurality of the notches, and
a density of the notches formed in a region of the connection member in which the distance from the power supply terminal in the predetermined direction is smaller than a predetermined distance is larger than the density of the notches formed in a region of the connection member in which the distance from the power supply terminal in the predetermined direction is equal to or larger than the predetermined distance.

13. The chamber device according to claim 10,
wherein the inductance compensation structure includes a plurality of the notches formed along the predetermined direction, and
an area of the notches formed in a region of the connection member in which the distance from the power supply terminal in the predetermined direction is smaller than a predetermined distance is larger than the area of the notches formed in a region of the connection member in which the distance from the power supply terminal in the predetermined direction is equal to or larger than the predetermined distance.

14. The chamber device according to claim 1,
wherein the inductance compensation structure includes a plurality of conductive plate portions arranged as being spaced apart from each other along the predetermined direction, and
a minimum value of a conductive width along the predetermined direction of the plate portion, close to the power supply terminal 320, at which the distance from the power supply terminal in the predetermined direction is smaller than a predetermined distance is smaller than a minimum value of a conductive width along the predetermined direction of the plate portion at which the distance from the power supply terminal in the predetermined direction is equal to or larger than the predetermined distance.

15. The chamber device according to claim 1,
wherein a capacitance of the capacitor arranged at a position at which the distance from the power supply terminal in the predetermined direction is equal to or larger than a predetermined distance is smaller than a capacitance of the capacitor arranged at a close position in which the distance from the power supply terminal in the predetermined direction is smaller than a predetermined distance.

16. The chamber device according to claim 1,
wherein a density of the capacitors arranged at positions at which the distances from the power supply terminal in the predetermined direction are equal to or larger than a predetermined distance is smaller than a density of the capacitors arranged at close positions in which the distances from the power supply terminal in the predetermined direction are smaller than the predetermined distance.

17. A gas laser device configured to amplify laser light by a chamber device and output the laser light,
the chamber device including:
a pair of discharge electrodes arranged with a longitudinal direction thereof oriented along a predetermined direction as being apart from and facing each other;
a chamber having an internal space at which the pair of discharge electrodes are arranged and a laser gas is enclosed;
a plurality of capacitors arranged in parallel along the predetermined direction;
at least one power supply terminal electrically connecting one of the discharge electrodes and one terminal of each capacitor to a high-voltage power source; and
a conductive plate-shaped connection member extending in the predetermined direction along the plurality of capacitors, electrically connected to the other terminal of each capacitor, and having a portion away from a side in connected to the other terminal the direction perpendicular to the predetermined direction be electrically connected to the chamber, and
the connection member including an inductance compensation structure that makes a distribution of inductance due to a distance between the power supply terminal and the one terminal of each of the capacitors close to be uniform.

18. An electronic device manufacturing method, comprising:
generating laser light using a gas laser device configured to amplify laser light by a chamber device and output the laser light;
outputting the laser light to an exposure apparatus; and
exposing a photosensitive substrate to the laser light in the exposure apparatus to manufacture an electronic device,
the chamber device including:
a pair of discharge electrodes arranged with a longitudinal direction thereof oriented along a predetermined direction as being apart from and facing each other;
a chamber having an internal space at which the pair of discharge electrodes are arranged and a laser gas is enclosed;
a plurality of capacitors arranged in parallel along the predetermined direction;
at least one power supply terminal electrically connecting one of the discharge electrodes and one terminal of each capacitor to a high-voltage power source; and
a conductive plate-shaped connection member extending in the predetermined direction along the plurality of capacitors, electrically connected to the other terminal of each capacitor, and having a portion away from a side connected to the other terminal in the direction perpendicular to the predetermined direction be electrically connected to the chamber, and
the connection member including an inductance compensation structure that makes a distribution of inductance due to a distance between the power supply terminal and the one terminal of each of the capacitors close to be uniform.
